(19) United States
(12) Patent Application Publication
(10) Pub. No.: US 2013/0260538 A1
(43) Pub. Date: Oct. 3, 2013

(54) METHOD OF MANUFACTURING GALLIUM NITRIDE SUBSTRATE

(71) Applicant: HITACHI CABLE, LTD., Tokyo (JP)

(72) Inventor: Hajime Fujikura, Mito (JP)

(73) Assignee: Hitachi Cable, Ltd., Tokyo (JP)

(21) Appl. No.: 13/844,894

(22) Filed: Mar. 16, 2013

(30) Foreign Application Priority Data
Mar. 28, 2012 (JP) 2012-073739

(51) Int. Cl. H01L 21/02

(52) U.S. Cl. CPC H01L 21/02389
USPC 438/478

(57) ABSTRACT

A method of manufacturing a gallium nitride substrate includes machining a gallium nitride crystal, and wet-etching the gallium nitride crystal prior to the machining.

The present application is based on Japanese patent application No.2012-073739 filed on Mar. 28, 2012, the entire contents of which are incorporated herein by reference.

### BACKGROUND OF THE INVENTION

1. Field of the Invention

The invention relates to a method of manufacturing a gallium nitride substrate for improving a production yield.

2. Description of the Related Art

One of nitride semiconductor substrates used for manufacturing electronic devices such as blue laser diode or blue light-emitting diode is a free-standing gallium nitride substrate obtained by machining a gallium nitride crystal which is grown by HVPE (Hydride Vapor Phase Epitaxy), etc.

For manufacturing one gallium nitride substrate from a gallium nitride crystal, firstly, a mechanical grinding process or polishing process is performed on front and back surfaces, i.e., a Ga-polar surface and an N-polar surface, of an as-grown crystal and outline processing is further performed to trim the shape. The as-grown crystal here refers to a gallium nitride crystal immediately after growth which is not machined at all.

On the other hand, for manufacturing multiple gallium nitride substrates from a gallium nitride crystal, multiple sliced substrates are firstly formed by slicing an as-grown crystal, and then, the above-mentioned grinding process, the polishing process and the outline processing are performed on the sliced substrates.

The gallium nitride substrates after the machining are used as semiconductor substrates for manufacturing optical devices or electronic devices.

### SUMMARY OF THE INVENTION

During the machining, cracks or fractures may occur since mechanical stress is applied to the as-grown crystal or the sliced substrates. Thereby, the production yield of the gallium nitride substrate may decrease.

Accordingly, it is an object of the invention to provide a method of manufacturing a gallium nitride substrate that is to prevent the occurrence of cracks or fractures even when stress is applied to a gallium nitride crystal during machining so as to improve the production yield of the substrate.

(1) According to one embodiment of the invention, a method of manufacturing a gallium nitride substrate comprises:
machining a gallium nitride crystal; and
wet-etching the gallium nitride crystal prior to the machining.

In the above embodiment (1) of the invention, the following modifications and changes can be made.
(i) The gallium nitride crystal comprises an as-grown crystal or a sliced substrate formed by slicing the as-grown crystal.
(ii) The machining comprises a plurality of process steps, wherein the wet-etching is conducted before each of the plurality of process steps.
(iii) A surface of the gallium nitride crystal except a C-plane is wet-etched.
(iv) An etching amount is not less than 5 μm in a direction perpendicular to a surface being etched.
(v) A liquid mixture of phosphoric acid and sulfuric acid is used for the wet-etching.
(vi) A mixture fraction of sulfuric acid to phosphoric acid is not less than 1/10 and not more than 10.
(vii) Temperature of the liquid mixture is not less than 200° C. and not more than 300° C.

### POINTS OF THE INVENTION

According to one embodiment of the invention, a method of manufacturing a gallium nitride substrate is conducted such that a part of the substrate that is likely to be subjected to cracks or fractures is chemically removed by wet-etching prior to machining. Thereby, it is possible to prevent the occurrence of cracks or fractures even if stress is applied to the gallium nitride crystal during the machining. Thus, the production yield of the substrate can be improved.

### BRIEF DESCRIPTION OF THE DRAWINGS

Next, the present invention will be explained in more detail in conjunction with appended drawings, wherein:

FIG. 1 is an explanatory diagram illustrating a mechanism of crack or fracture occurrence in a gallium nitride crystal during machining;

FIG. 2 is a diagram illustrating a relation between an etching amount and a production yield when one gallium nitride substrate having a diameter of 100 mm is manufactured from a 3 mm-thick as-grown crystal having a diameter of 110 mm; and

FIG. 3 is a diagram illustrating a relation between an etching amount and a production yield when twenty-five gallium nitride substrates each having a diameter of 150 mm are manufactured by slicing a 50 mm-thick as-grown crystal having a diameter of 160 mm.

### DETAILED DESCRIPTION OF THE PREFERRED EMBODIMENTS

A preferred embodiment of the invention will be described below in conjunction with the appended drawings.

Firstly, a mechanism of crack or fracture occurrence during machining will be described.

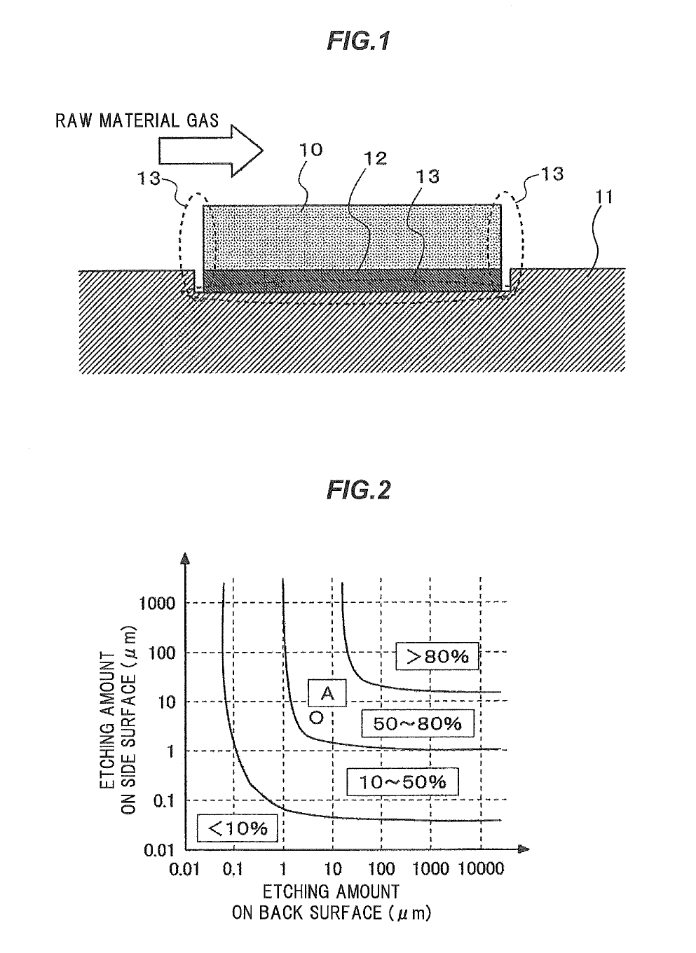

As shown in FIG. 1, a thick gallium nitride film is grown by supplying a raw material gas on a base substrate 12 held in a holder 11, thereby manufacturing an as-grown crystal 10. Growth conditions such as temperature, growth rate and a mole ratio of a gallium raw material to a nitrogen raw material (a V/III ratio), etc., are adjusted so that the as-grown crystal 10 formed of the thick gallium nitride film is grown on the front surface of the base substrate 12 while maintaining high quality. However, since the condition of the as-grown crystal 10 on the side surface and in the vicinity of the bottom of the base substrate 12 is different from the front surface, a brittle low-quality crystal is grown on such portions 13. Cracks or fractures are likely to occur in the portions 13 at the time of machining as compared to other portions.

In addition, also in a sliced substrate which is obtained by slicing the as-grown crystal 10, defective portions such as flaw are newly introduced due to the slicing. Cracks or fractures are likely to occur also in the defective portions at the time of machining as compared to other portions.

Accordingly, in the invention, portions where cracks or fractures are likely to occur are preliminarily removed prior to machining to suppress occurrence of cracks or fractures during the machining, thereby improving a product yield.

That is, in the invention, a method of manufacturing a gallium nitride substrate in which a gallium nitride substrate is manufactured by machining a gallium nitride crystal includes wet-etching of the gallium nitride crystal prior to the machining.

Note that, the gallium nitride crystal is an as-grown crystal or a sliced substrate formed by slicing the as-grown crystal.

In more detail, in case that one gallium nitride substrate is manufactured from one as-grown crystal and when a gallium nitride substrate is manufactured by machining the as-grown crystal, the gallium nitride crystal is wet-etched prior to the machining.

Meanwhile, in case that multiple gallium nitride substrates are manufactured from one as-grown crystal and when a gallium nitride substrate is manufactured by machining a sliced substrate formed by slicing the as-grown crystal, the sliced substrate is wet-etched prior to the machining.

In the latter case, the machining includes a slicing process for making sliced substrates from the as-grown crystal, a grinding process or outline processing for equalizing thickness or outer shape of the sliced substrates and a polishing process for obtaining a flat growth surface, etc. In the former case, the machining includes the grinding process, the outline processing and the polishing process, etc.

Thus, the machining includes plural process steps, and wet-etching should be performed at least prior to the first process step but is preferably performed prior to each process step. As a result, it is possible to preliminarily remove a defective portion newly introduced during the process step or a portion of the as-grown crystal in which cracks or fractures are likely to occur, thereby suppressing occurrence of cracks or fractures in the following process steps.

Since the portion in which cracks or fractures are likely to occur when manufacturing one gallium nitride substrate from one as-grown crystal is present mainly on surfaces other than the front surface, i.e., other than a C-plane (Ga-polar surface) of the as-grown crystal of which growth conditions are well controlled as described above, it is preferable to wet-etch the surfaces of the as-grown crystal other than the C-plane. Here, the surfaces other than the C-plane mean the back and side surfaces (an A-plane, an M-plane and a plane therebetween) of the as-grown crystal (base substrate 12).

It should be noted that, in the wet-etching, etch pits are slightly generated on the C-plane of the as-grown crystal but the C-plane which is a Ga-polar surface is chemically very stable and is not significantly wet-etched.

Therefore, it is possible to wet-etch the surfaces of the as-grown crystal other than the C-plane by general wet-etching without any special means. Then, the gallium nitride substrate is washed and cleaned by water after the wet-etching.

Meanwhile, when multiple gallium nitride substrates are manufactured by slicing one as-grown crystal, a defective portion is introduced during the slicing. The defective portion (a low-quality portion in which cracks or fractures are likely to occur) is thus present also on the C-plane and the N-polar surface of the sliced substrate, and it is therefore preferable to wet-etch the all surfaces of the sliced substrate. At this time, the low-quality portion on the Ga-polar surface of the sliced substrate is chemically unstable and is thus removed by wet-etching, but a high-quality Ga-plane subsequently exposed is chemically very stable and is thus not significantly etched.

Furthermore, it is preferable that an etching amount be not less than 5 μm in a vertical direction from each etching surface excluding the C-plane either in the case of the former or in the case of the latter. It is because this allows a production yield to be significantly improved (e.g., by 40% or more). In an illustrative embodiment, a relation between the etching amount and the production yield is as shown in FIG. 2 when one gallium nitride substrate having a diameter of 100 mm is manufactured from a 3 mm-thick as-grown crystal having a diameter of 110 mm.

As understood from FIG. 2, while the product yield is less than 10% when the wet-etching is not performed prior to the machining, i.e., when the etching amount on the side and back surfaces is 0 μm, the product yield is improved with an increase in the etching amount on the side and back surfaces when the wet-etching is performed.

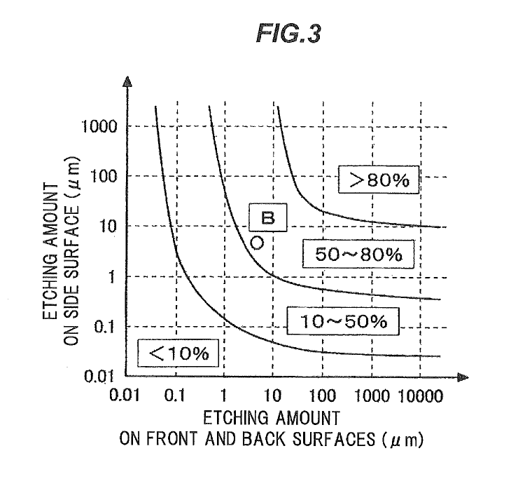

Meanwhile, a relation between the etching amount and the production yield is as shown in FIG. 3 when twenty-five sliced substrates each having a diameter of 150 mm are manufactured by slicing a 50 mm-thick as-grown crystal having a diameter of 160 mm.

As understood from FIG. 3, while the product yield is less than 10% when the wet-etching is not performed prior to the machining, i.e., when the etching amount on the side, front and back surfaces is 0 μm, the product yield is improved with an increase in the etching amount when the wet-etching is performed. Considering these results, it is preferable that the etching amount be not less than 5 μm in a vertical direction from each etching surface as indicated by points A and B in FIGS. 2 and 3 in order to significantly improve the production yield and also to obtain a stable result. As a result, the production yield can be increased by 40% or more. Furthermore, the production yield can be increased to not less than 80% when the etching amount is not less than 100 μm.

The above-mentioned wet-etching may be performed by any methods and can be performed using, e.g., an etchant made of potassium hydroxide or a liquid mixture of phosphoric acid and sulfuric acid.

When the wet-etching is performed using the liquid mixture of phosphoric acid and sulfuric acid, it is preferable that a mixing ratio of sulfuric acid to phosphoric acid be from 10:1 to 1:10, i.e., a mixture fraction of sulfuric acid to phosphoric acid be not less than 1/10 and not more than 10 in order to realize suitable wet-etching. By changing this ratio, the etching amount on the front, back and side surfaces of the gallium nitride crystal or the sliced substrate can be made different from each other or etching time can be adjusted.

In addition, it is preferable that temperature of the liquid mixture be not less than 200° C. and not more than 300° C. This is because the wet-etching does not progress when the temperature of the liquid mixture is less than 200° C. and, when more than 300° C., phosphoric acid deteriorates and it is not possible to perform suitable wet-etching.

As described above, in the method of manufacturing a gallium nitride substrate of the invention, since the portion in which cracks or fractures are likely to occur is chemically removed by wet-etching prior to machining, it is possible to prevent cracks or fractures from occurring even if stress is applied to the gallium nitride crystal during the machining, thereby improving the production yield.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A method of manufacturing a gallium nitride substrate, comprising:
machining a gallium nitride crystal; and
wet-etching the gallium nitride crystal prior to the machining.

2. The method according to claim 1, wherein the gallium nitride crystal comprises an as-grown crystal or a sliced substrate formed by slicing the as-grown crystal.

3. The method according to claim 1, wherein the machining comprises a plurality of process steps, and
wherein the wet-etching is conducted before each of the plurality of process steps.

4. The method according to claim 1, wherein a surface of the gallium nitride crystal except a C-plane is wet-etched.

5. The method according to claim 1, wherein an etching amount is not less than 5 μm in a direction perpendicular to a surface being etched.

6. The method according to claim 1, wherein a liquid mixture of phosphoric acid and sulfuric acid is used for the wet-etching.

7. The method according to claim 6, wherein a mixture fraction of sulfuric acid to phosphoric acid is not less than 1/10 and not more than 10.

8. The method according to claim 6, wherein temperature of the liquid mixture is not less than 200° C. and not more than 300° C.
